(19) United States
(12) Patent Application Publication
(10) Pub. No.: US 2025/0201594 A1
(43) Pub. Date: Jun. 19, 2025

(54) MODULAR PROCESSING CHAMBERS AND RELATED HEATING CONFIGURATIONS, METHODS, APPARATUS, AND MODULES FOR SEMICONDUCTOR MANUFACTURING

(71) Applicant: Applied Materials, Inc., Santa Clara, CA (US)

(72) Inventors: Ala MORADIAN, Sunnyvale, CA (US); Umesh M. KELKAR, Santa Clara, CA (US); Saurabh CHOPRA, Santa Clara, CA (US); Prashanth KOTHNUR, San Jose, CA (US); Ananth Nuggehalli BHOJ, Round Rock, TX (US); Yunho KIM, Milpitas, CA (US); Phillip STOUT, Santa Clara, CA (US); Zuoming ZHU, Sunnyvale, CA (US)

(21) Appl. No.: 18/539,083

(22) Filed: Dec. 13, 2023

(51) Int. Cl. H01L 21/67; C23C 16/458; C23C 16/46; C23C 16/505; H01J 37/32; H01L 21/02

(52) U.S. Cl. CPC H01L 21/67109; C23C 16/4583; C23C 16/46; C23C 16/505; H01J 37/3211; H01J 37/32522; H01J 37/32568; H01L 21/02532; H01L 21/0262; H01J 2237/332

(57) ABSTRACT

The present disclosure relates to modular processing chambers, and related methods, apparatus, modules, and components for semiconductor manufacturing. In one or more embodiments, a processing chamber applicable for use in semiconductor manufacturing includes a chamber body and a plate. The chamber body includes an inject section and an exhaust section. The chamber body and the plate at least partially define a processing volume. The plate includes at least one opaque surface. The processing chamber includes one or more heat sources configured to heat the processing volume, and a substrate support disposed in the processing volume and above the one or more heat sources. The plate is disposed between the substrate support and a lid of the processing chamber.

### BACKGROUND

### Field

The present disclosure relates to modular processing chambers, and related methods, apparatus, modules, and components for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, operations (such as epitaxial deposition operations) can be long, expensive, and inefficient, and can have limited capacity and throughput. Operations can also be limited with respect to application modularity. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration. The activation of gases can be limited, for example, at relatively low processing temperatures for device production (such as complementary field-effect transistor (CFET) devices). Moreover, relatively higher processing temperatures can involve unintended dopant diffusion and/or hindered device performance.

Therefore, a need exists for improved apparatuses and methods in semiconductor processing.

### SUMMARY

The present disclosure relates to modular processing chambers, and related methods, apparatus, modules, and components for semiconductor manufacturing.

In one or more embodiments, a processing chamber applicable for use in semiconductor manufacturing includes a chamber body and a plate. The chamber body includes an inject section and an exhaust section. The chamber body and the plate at least partially define a processing volume. The plate includes at least one opaque surface. The processing chamber includes one or more heat sources configured to heat the processing volume, and a substrate support disposed in the processing volume and above the one or more heat sources. The plate is disposed between the substrate support and a lid of the processing chamber.

In one or more embodiments, a processing chamber applicable for use in semiconductor manufacturing includes a chamber body and a window. The chamber body includes an inject section and an exhaust section. The chamber body and the window at least partially define a processing volume. The processing chamber includes one or more heat sources configured to heat the processing volume, and a substrate support disposed in the processing volume and above the one or more heat sources. The processing chamber includes a reflector disposed outwardly of the window relative to the substrate support, and an energy source operable to supply a plasma in the processing volume.

In one or more embodiments, a method of substrate processing includes heating a substrate positioned on a substrate support of a processing chamber from one side of the substrate. The method includes supplying a plasma in a processing volume of a processing chamber, flowing one or more process gases over the substrate, and depositing one or more layers on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic partial top cross-sectional view of the conductive plate shown in FIG. 1, according to one or more embodiments.

FIG. 3 is a schematic side cross-sectional view of a processing chamber, according to one or more embodiments.

FIG. 4 is a schematic side cross-sectional view of a processing chamber, according to one or more embodiments.

FIG. 5 is a schematic side cross-sectional view of a processing chamber, according to one or more embodiments.

FIG. 6 is a schematic partial top view of a zonal arrangement for zones of heat sources, according to one or more embodiments.

FIG. 7 is a schematic partial top view of a heat source module, according to one or more embodiments.

FIG. 8 is a schematic partial bottom perspective view of the heat source module shown in FIG. 7, according to one or more embodiments.

FIG. 9 is a schematic partial perspective view of one of the heat sources shown in FIG. 7, according to one or more embodiments.

FIG. 10 is a schematic partial perspective view of a heat source, according to one or more embodiments.

FIG. 11 is a schematic cross-sectional side view of a processing chamber, according to one or more embodiments.

FIG. 12 is a schematic side cross-sectional view of a processing chamber, according to one or more embodiments.

FIG. 13 is a schematic side cross-sectional view of a processing chamber, according to one or more embodiments.

FIG. 14 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to modular processing chambers, and related methods, apparatus, modules, and components for semiconductor manufacturing.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

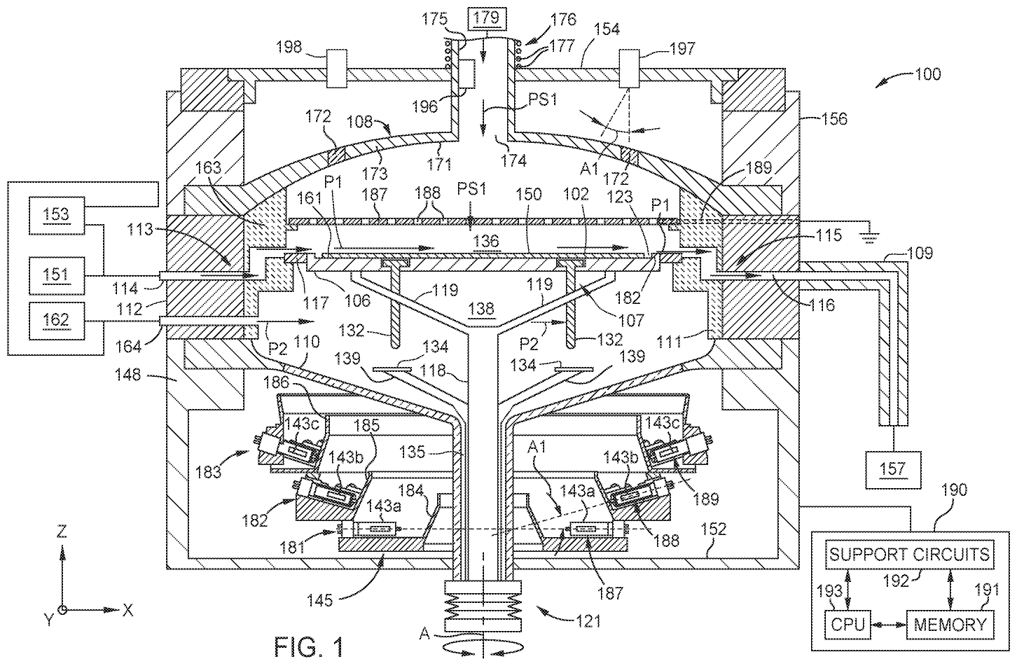

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102, and the processing chamber 100 is used to supply a plasma for plasma operations (such as plasma-assisted film deposition, ion implantation into the substrate 102, pre-cleaning of the substrate 102, etching of the substrate 102, and/or cleaning of the processing chamber 100). In one or more embodiments, the processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, a plate 108, one or more heat sources 143, and a window 110 (e.g., a lower window, for example a lower dome). The window 110 is formed of an energy transmissive material, such as transparent quartz. In one or more embodiments, the plate 108 includes at least one opaque surface 171. In one or more embodiments, the plate 108 includes a transparent section 172 (two or more can be included) and an opaque section 173 (two or more can be included). In one or more embodiments, the plate 108 is a window, such as an upper window, for example an upper dome. In such an embodiment, the plate 108 is formed of an energy transmissive material, such as transparent quartz. The one or more heat sources 143 include a plurality of lower heat sources 143 operable to heat a processing volume 136 from one side of the substrate 102 (e.g., from below the substrate 102). The chamber body and the plate 108 at least partially define the processing volume 136. In one or more embodiments, the lower heat sources 143 include lamps (such as halogen lamps or UV lamps). The present disclosure contemplates that other heat sources may be used (in addition to or in place of the lamps) for the various heat sources described herein. For example, resistive heaters, microwave powered heaters, light emitting diodes (LEDs), lasers (e.g., laser diodes), and/or or any other suitable heat source singly or in combination may be used for the various heat sources described herein.

The substrate support 106 is disposed in the processing volume 136 and between the plate 108 and the window 110. The substrate support 106 is disposed above the one or more heat sources 143, and the substrate support 106 supports the substrate 102. The plate 108 is disposed between the substrate support 106 and a lid 154 of the processing chamber 100. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of lower heat sources 143 are disposed between the window 110 and a floor 152. The plurality of lower heat sources 143 form a portion of a lower heat source module 145.

The processing volume 136 and a purge volume 138 are between the plate 108 and the window 110. The processing volume 136 and the purge volume 138 are part of an internal volume of the processing chamber 100. One or more liners 111, 163 are disposed inwardly of the chamber body.

The substrate support 106 includes a top surface on which the substrate 102 is disposed. The substrate support 106 is coupled to a shaft 118. In one or more embodiments, the substrate support 106 is coupled to the shaft 118 through one or more arms 119 coupled to the shaft 118. The shaft 118 is coupled to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 are part of an inject portion 113 of the chamber body, and the one or more gas exhaust outlets 116 are part of an exhaust portion 115 of the chamber body. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The pre-heat ring 117 can include a complete ring or one or more ring segments. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phosphine (PH₃), and the one or more cleaning gases include hydrochloric acid (HCl).

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111.

During a deposition operation (e.g., an epitaxial growth operation), the one or more process gases P1 flow through the one or more gas inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The plate 108 includes a plate opening 174. The processing chamber 100 includes a conduit 175 in fluid communication with the plate opening 174, and an energy source 176 operable to supply a plasma PS1 in the processing volume 136. In one or more embodiments, the energy source 176 includes one or more radio frequency (RF) coils 177 disposed at least partially about the conduit 175. A gas G1 flows through the conduit 175 while electrical power (such as an RF current) flows through the one or more RF coils 177 such that a voltage is applied across the gas G1. The voltage ignites the gas G1 into the plasma PS1. The plasma PS1 then flows into the processing volume 136. The gas G1 used to generate the plasma PS1 may include but is not limited to one or more of: hydrogen (H₂), xenon (Xe₂), fluorine (F₂), krypton fluoride (KrF), neon (Ne), and/or any mixtures thereof (such as xenon and neon). In one or more embodiments, the gas G1 includes one or more silicon-containing gases (e.g., silane, dichlorosilane (DCS), trichlorosilane (TCS), disilane (DS), and/or tetraclorosilane) mixed with a carrier gas (e.g., argon, hydrogen, and/or helium). In one or more embodiments, the gas G1 includes one or more dopant gases, such as germane, diborane, and/or phosphorous. Other gases are contemplated for the gas G1. The gas G1 can be supplied from a plasma gas source 179. The present disclosure contemplates that a voltage and/or a frequency of RF power applied to the one or more RF coils 177 can be varied and/or pulsed. The frequency can involve a single frequency or multiple frequencies. The multiple frequencies can be combined.

The processing chamber 100 includes a conductive plate 187 disposed between the substrate support 106 and the plate 108. The conductive plate 187 includes a plurality of flow openings 188, and the plasma PS1 flows through the flow openings 188 and into the processing volume 136. The conductive plate 187 is formed of a conductive material. In one or more embodiments, the conductive material includes silicon carbide (SiC), molybdenum, tungsten, stainless steel, and/or aluminum (such as anodized aluminum). The conductive plate 187 can function as an ion filter (e.g., an ion blocker plate) such that, as the plasma PS1 flows past the conductive plate 187, radicals flow through the flow openings 188 and past the conductive plate 187 while ions are at least partially blocked by the conductive plate 187 and conduct through the conductive plate and to ground through a ground electrode 189. The ground electrode 189 extends into the conductive plate 187 on a side aligned with the exhaust portion 115 of the processing chamber 100.

The plasma PS1 can be supplied in the processing volume 136 during the flowing of the one or more process gases P1 (and/or the cleaning gases) to facilitate breaking bonds, e.g., for deposition on the substrate 102. The plasma PS1 can be supplied in the processing volume 136 before the flowing of the one or more process gases P1 (e.g., to pre-clean the substrate 102), or after the flowing of the one or more process gases P1 (e.g., to etch the substrate 102, supply ions into the substrate 102, and/or to clean the processing chamber 100). The present disclosure contemplates that the one or more process gases P1 can be supplied through the conduit 175 and/or the one or more gas inlets 114 can be omitted. The present disclosure also contemplates that the plasma PS1 can be supplied through the one or more gas inlets 114 and/or the energy source 176 can be omitted or disposed adjacent to the flow module 112.

The processing chamber 100 includes one or more sensor devices 195, 196, 197, 198 (e.g., metrology sensors, and/or temperature sensors) configured to measure parameter(s) (e.g., temperature(s)) within the processing chamber 100 and/or metrology parameter(s) of the substrate 102). In one or more embodiments, the one or more sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, one or more of the sensor devices 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature. For example, one or more of the sensor devices 195, 196, 197, 198 can measure one or more gas parameters and/or one or more plasma parameters (such as ion density, electron temperature, electron density, ion energy and angle distribution, enthalpy, radical density, and/or absorption). In one or more embodiments, one or more of the sensor devices 195, 196, 197, 198 include a residual gas analyzer, an optical emission spectrometer, an enthalpy probe, a Langmuir probe, Faraday cup, and/or an absorption spectrometer.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

The present disclosure contemplates that all sensor devices can be disposed above the plate 108 and/or on or adjacent to the lid 154. For example, the one or more lower sensor devices 195 can be omitted. The one or more upper sensor devices 196, 197, 198 can view through an opening defined by the conduit 175 and/or the transparent section(s) 172 of the plate 108.

Each sensor device 195, 196, 197, 198, can be a single-wavelength sensor device or a multi-wavelength (such as dual-wavelength) sensor device. In one or more embodiments, the processing chamber 100 includes any one, any two, or any three of the four illustrated sensor devices 195, 196, 197, 198. In one or more embodiments, the processing chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the pre-heat ring 11, the substrate support 106, and/or the liners 111, 163. As an example, one or more sensor devices 195, 196, 197, 198 can measure temperatures of the substrate 102 and/or the pre-heat ring 117, and power to the one or more heat sources 143 and/or the energy source 176 can be controlled based on the measured temperatures (e.g., using a feedback control). As described the one or more sensor devices can include, for example pyrometers. In one or more embodiments, one or more thermocouples (e.g., proximity thermocouples) can be used in addition to or in place of the pyrometers, and power to the one or more heat sources 143 and/or the energy source 176 can be controlled based on the measured temperatures (e.g., using a feedback control).

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power supplied to the one or more heat sources 143 and/or the energy source 176, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations (such as operations of the method 1400) described herein. The instructions stored on the memory, when executed, cause one or more of the operations (such as operations of the method 1400) described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the one or more heat sources 143 and/or the energy source 176, the deposition, the cleaning, the rotational position, the heating, and gas flow through the processing chamber 100 by providing an output to the controls for the sensor devices 195, 196, 197, 198, the one or more heat sources 143 and/or the energy source 176, the process gas source 151, the purge gas source 162, the motion assembly 121, and/or the exhaust pump 157.

During processing, in one or more embodiments, the substrate 102 is heated to a target temperature of 400 degrees Celsius or higher or 600 degrees Celsius or less. In one or more embodiments, the target temperature for the substrate 102 is within a range of 380 degrees Celsius to 600 degrees Celsius, for example 400 degrees Celsius to 500 degrees Celsius. In one or more embodiments, the target temperature for the substrate 102 is less than 500 degrees Celsius. In one or more embodiments, the target temperature for the substrate 102 is 400 degrees Celsius or less, such as less than 200 degrees Celsius (for example about 150 degrees Celsius).

The one or more heat sources 143 include a plurality of heat sources 143a-143c arranged in a plurality of levels 181-183. The plurality of levels 181-183 includes a first level 181 of one or more first heat sources 143a and a second level 182 of one or more second heat sources 143b oriented at an angle A1 (e.g., an oblique angle) relative to the first level 181. The plurality of levels 183 include a third level 183 of one or more third heat sources 143c. The processing chamber 100 includes a first reflector 184 disposed inwardly of the first level 181 of one or more first heat sources 143a, a second reflector 185 disposed inwardly of the second level 182 of one or more second heat sources 143b, and a third reflector 186 disposed inwardly of the third level 183 of one or more third heat sources 143c. The plurality of heat sources 143a-143c are arranged in a plurality of zones 186-188 (three zones are shown in FIG. 1). In one or more embodiments, the first level 181 of one or more first heat sources 143a are oriented perpendicularly to a longitudinal axis LA1 of the substrate support 106, and the second level 182 of one or more second heat sources 143b and the third level 183 of one or more third heat sources 143c are oriented at an oblique angle relative to the longitudinal axis LA1.

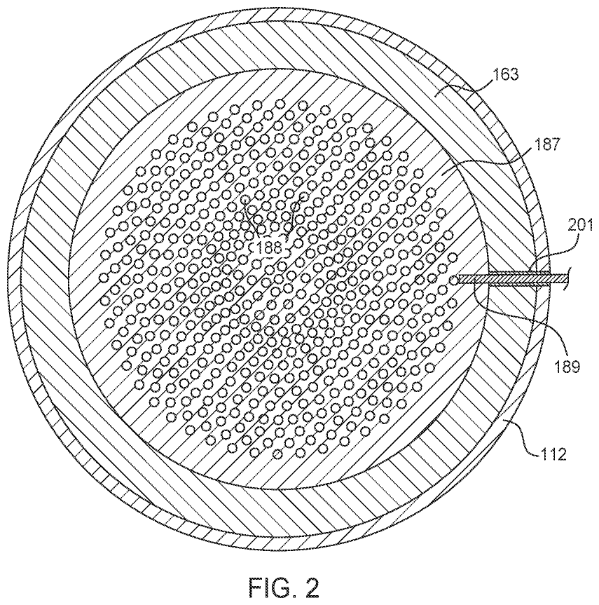

FIG. 2 is a schematic partial top cross-sectional view of the conductive plate 187 shown in FIG. 1, according to one or more embodiments.

A sleeve 201 is disposed about the ground electrode 189. The sleeve 201 can be disposed in the upper liner 163 and the flow module 112.

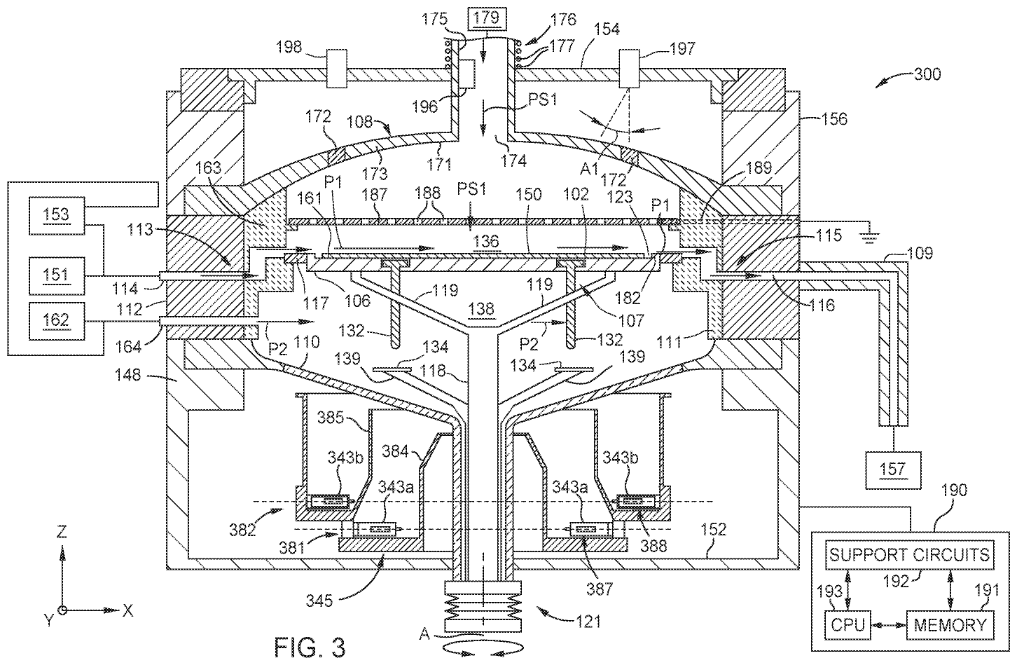

FIG. 3 is a schematic side cross-sectional view of a processing chamber 300, according to one or more embodiments.

The processing chamber 300 is similar to the processing chamber 100 shown in FIG. 1, and includes one or more aspects, features, components, operations, and/or properties thereof.

The processing chamber 300 includes a heat source module 345 disposed below the substrate support 106. The heat source module 345 includes one or more heat sources 343. The one or more heat sources 343 include a plurality of heat sources 343a-343b arranged in a plurality of levels 381, 382. The plurality of levels 381, 382 includes a first level 381 of one or more first heat sources 343a and a second level 382 of one or more second heat sources 343b oriented parallel to the first level 381. The heat source module 345 of the processing chamber 300 includes a first reflector 384 disposed inwardly of the first level 381 of one or more first heat sources 343a, a second reflector 385 disposed inwardly of the second level 382 of one or more second heat sources 343b. The plurality of heat sources 343a, 343b are arranged in a plurality of zones 386, 387 (two zones are shown in FIG. 3). In one or more embodiments, the first level 381 of one or more first heat sources 343a and the second level 382 of one or more second heat sources 343b are oriented perpendicularly to the longitudinal axis LA1 of the substrate support 106.

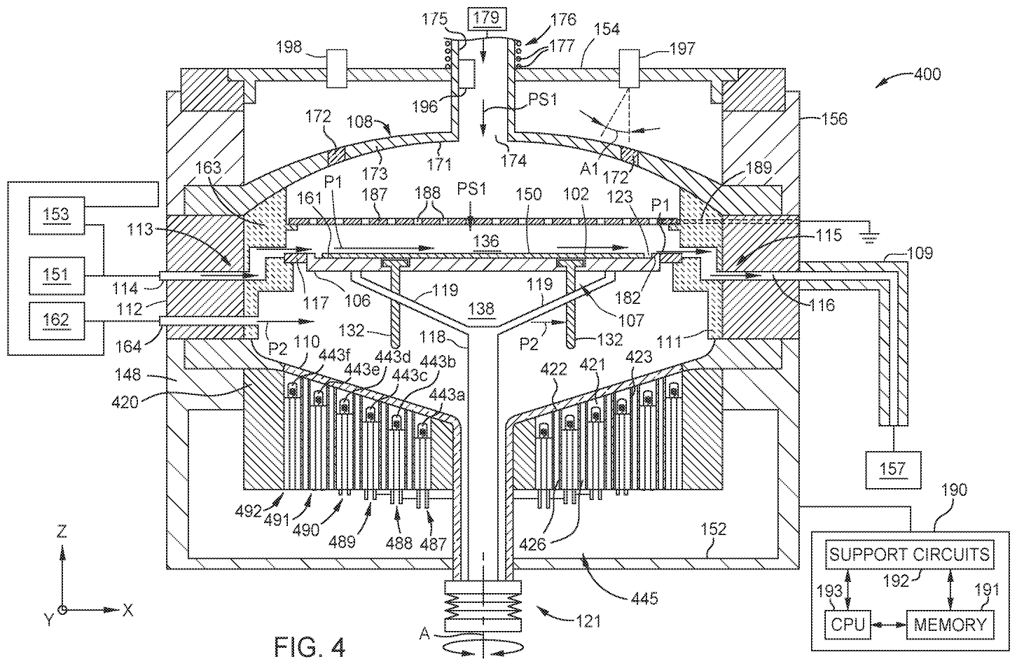

FIG. 4 is a schematic side cross-sectional view of a processing chamber 400, according to one or more embodiments.

The processing chamber 400 is similar to the processing chamber 100 shown in FIG. 1, and includes one or more aspects, features, components, operations, and/or properties thereof.

The processing chamber 400 includes a heat source module 445 disposed below the substrate support 106. The heat source module 445 includes one or more heat sources 443. The one or more heat sources 443 include a plurality of heat sources 443a-443f arranged in a plurality of zones 487-492 (six zones are shown in FIG. 4). The heat source module 345 of the processing chamber 400 includes a reflector housing 420, and the heat sources 443a-443f are disposed respectively in openings 421 of the reflector housing 420. The reflector housing 420 can be formed of a reflective material (such as gold or polished aluminum) and/or can be coated with the reflective material. For example, an upper surface 422 and/or interior surfaces 423 adjacent the openings 421 can be coated with the reflective material. A plurality of cooling channels 426 are formed in the reflector housing 420 and between the respective openings 421. The cooling channels 426 can receive a cooling fluid, such as air or water. In one or more embodiments, the plurality of heat sources 443a-443f are oriented parallel to the longitudinal axis LA1 of the substrate support 106.

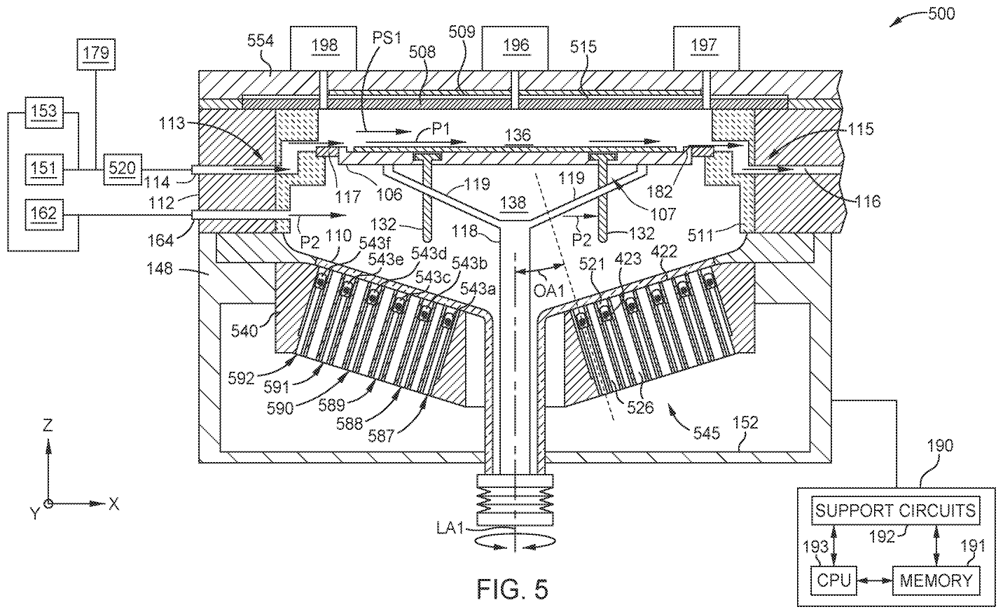

FIG. 5 is a schematic side cross-sectional view of a processing chamber 500, according to one or more embodiments.

The processing chamber 500 is similar to the processing chamber 100 shown in FIG. 1, and includes one or more aspects, features, components, operations, and/or properties thereof.

The processing chamber 500 includes one or more liners 511, 563 (e.g., a lower liner 511 and an upper liner 563) and a plate 508. The plate 508 is similar to the plate 108, and includes one or more aspects, features, components, operations, and/or properties thereof. In one or more embodiments, the plate 508 is a window and is transparent (e.g., is formed of a transparent quartz). A reflector 509 is disposed outwardly of the plate 508 relative to the substrate support 106. The reflector 509 is disposed between the plate 508 and a lid 554. A cavity 515 is between the reflector 509 and the plate 508. In one or more embodiments, the reflector 509 includes a reflective plate or a plate coated with the reflective material. The processing chamber 500 includes an energy source 520 operable to supply the plasma PS1 in the processing volume 136. The energy source 520 applies RF power to flowing gas G1 to generate the plasma PS1 outside of the processing volume.

The processing chamber 500 includes a heat source module 545 disposed below the substrate support 106. The heat source module 545 includes one or more heat sources 543. The one or more heat sources 543 include a plurality of heat sources 543a-543f arranged in a plurality of zones 587-592 (six zones are shown in FIG. 5). The heat source module 545 of the processing chamber 500 includes a reflector housing 540, and the heat sources 543a-543f are disposed respectively in angled openings 521 of the reflector housing 540. The reflector housing 540 is similar to the reflector housing 420 shown in FIG. 4, and includes one or more aspects, features, components, operations, and/or properties thereof. A plurality of cooling channels 526 are formed in the reflector housing 540 and between the respective angled openings 521. In one or more embodiments, the plurality of heat sources 543a-543f are oriented parallel to the longitudinal axis LA1 of the substrate support 106. The plurality of heat sources 543a-543f are oriented at an oblique angle OA1 relative to the longitudinal axis LA1 of to the substrate support 106.

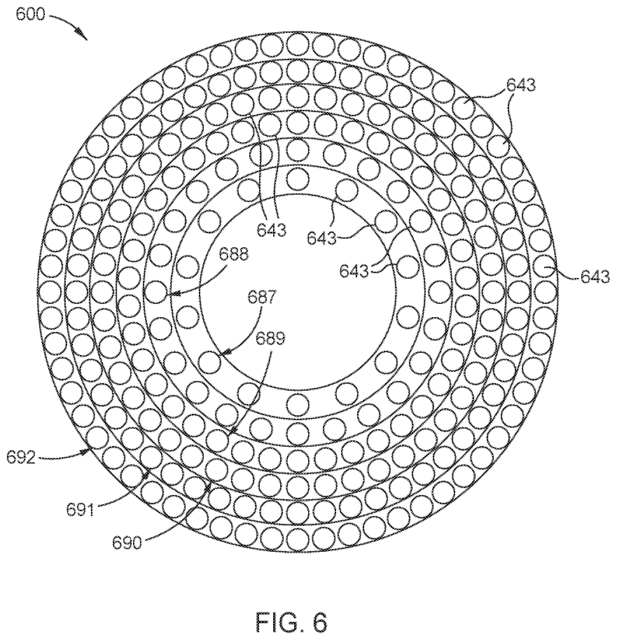

FIG. 6 is a schematic partial top view of a zonal arrangement 600 for zones of heat sources, according to one or more embodiments.

A plurality of heat sources 643 are arranged in a plurality of zones. The zones of the zonal arrangement 600 include a plurality of annular zones 687-692. The annular zones 687-692 can be independently controlled relative to each other. The annular zones 687-692 can be concentric with respect to each other. In one or more of the respective annular zones 687-692, the respective annular zone 687-692 can include one or more azimuthal zones that can be independently controlled relative to each other.

The zonal arrangement 600 can be used for any of the zones of heat sources described herein. As an example, the zones 487-492 of the heat sources 443a-443f shown in FIG. 4 can be arranged in the zonal arrangement 600. As another example, the zones 587-592 of the heat sources 543a-543f shown in FIG. 5 can be arranged in the zonal arrangement 600. For example, upper ends of the angled openings 521 can be arranged at the positions of the heat sources 643 shown in FIG. 6.

The present disclosure contemplates that the zones can be in shapes other than arcuate (e.g., annular) shapes. For example, the zones of the heat sources 643 can be arranged in a polygonal shape, such as a hexagonal shape (e.g., a close-packed hexagonal shape).

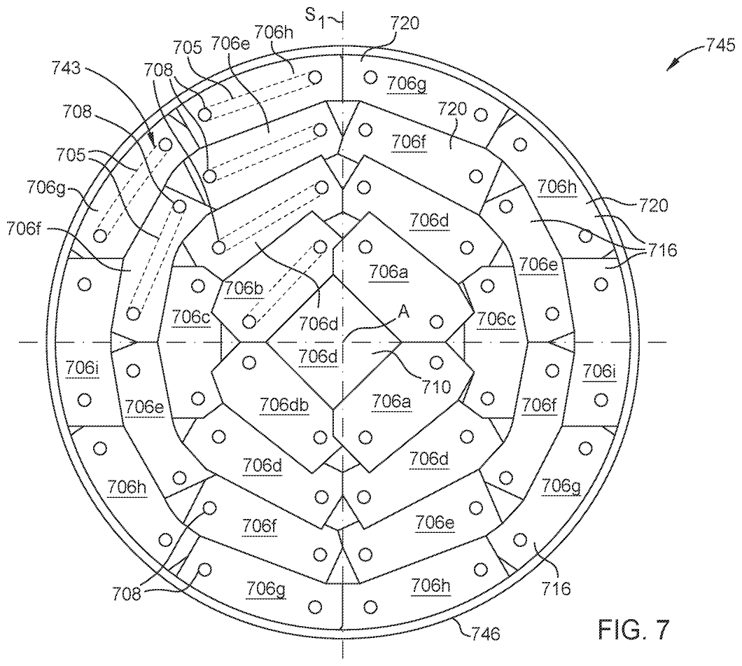

FIG. 7 is a schematic partial top view of a heat source module 745, according to one or more embodiments.

The heat source module 745 can be used in place of or in addition to one or more of: the heat source module 145, the heat source module 345, the heat source module 445, or the heat source module 545 described herein. The heat source module 745 can include one or more aspects, features, components, operations, and/or properties of one or more of: the heat source module 145, the heat source module 345, the heat source module 445, or the heat source module 545 described herein.

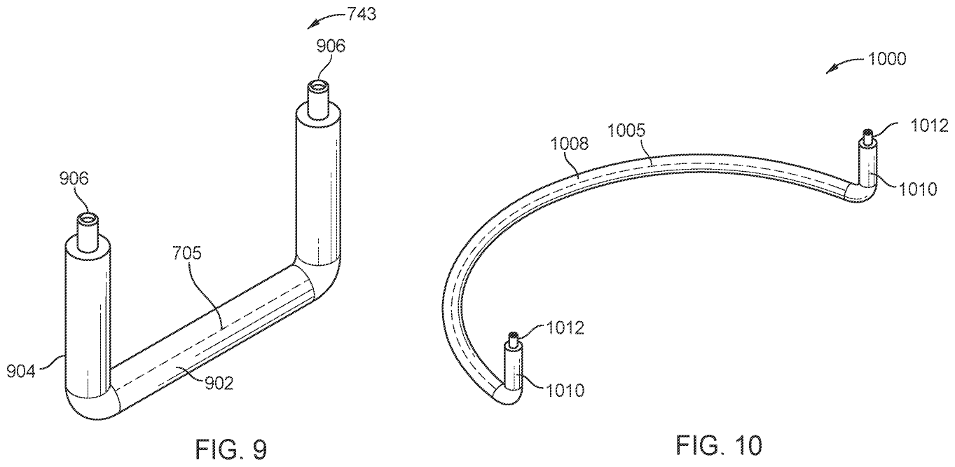

The heat source module 745 includes a support plate 746 and a plurality of heat sources 743 mounted to the support plate 746 through a plurality of mount bars 747 (shown in FIG. 9) coupled to the support plate 746. The support plate 746 and/or the mount bars 747 can be formed of the reflective material (such as gold, steel, aluminum, copper nickel, brass, bronze, silver, and/or an alloy thereof) and/or can be coated with the reflective material. The support plate 746 can be polished to increase reflectivity. In one or more embodiments, the mount bars 747 are mounted to a first side (e.g., a back side) of the support plate 746, and the heat sources 743 extend through the support plate 746 and to a second side (e.g., a front side) of the support plate 746. The heat sources 743 are arranged in a plurality of zones 787-790 (four zones are shown in FIG. 7). In one or more embodiments, the second side of the support plate 746 has a reflectivity greater than about 90%, such as greater than about 98% for wavelengths of about 150 nm or higher, such as 150 nm to about 15000 nm, such as about 700 nm to about 15000 nm, about 700 nm to 1000 nm, or about 1000 nm to about 15000 nm. In one or more embodiments, the second side of the support plate 746 has a reflectivity greater than about 90%, such as greater than about 98% for wavelengths in the infrared range and/or the ultraviolet range.

The support plate 746 includes a plurality of grooves 706a-706i formed in the second side shown in FIG. 7. The plurality of grooves 706a-706i are configured to hold a respective heat source 743. Respective walls 716 of the plurality of grooves 706a-706i have a generally elliptical, round, parabolic, or ovoid cross section and are configured to direct energy emitted by heat source(s) towards the substrate 102 within the processing chamber 100.

In one or more embodiments, the plurality of grooves 706a-706i are arranged along concentric rings. For example, a first ring is formed by a plurality of first grooves 706a and a plurality of second grooves 706b are disposed along a first ring, and a plurality of third grooves 706c and a plurality of fourth grooves 706d are disposed along a second ring.

The individual grooves of the plurality of grooves 706a-706i respectively have at least one hole 708 formed therethrough. The hole 708 extends to the first side of the support plate 746 and enables an electrical connection of a heat source 743 to be disposed therethrough. In one or more embodiments, the individual grooves of the grooves 706a-706i respectively include at least two holes 708, such as two holes 708. The holes 708 are located proximate to the distal ends of the grooves 706a-706i, such that one hole 708 is located at one distal end of one of the individual groove and a second hole 708 is located at the opposite distal end of the same individual groove. In addition to providing electrical support, the holes 708 may serve to allow for mechanical support of the lamps disposed within each of the grooves 706a-706i (e.g., using the mount bars 747). In one or more embodiments, the heat sources 743 respectively in the grooves 706a-706i include lamps that are at least partially linear, and include filaments 705 (six are shown in FIG. 7, in ghost, for clarity). The respective filaments 705 are disposed between two holes 708 formed in the respective grooves 706a-706i. A planar surface 710 can be disposed inwardly of the grooves 706a-706i and at or adjacent a central axis A of the support plate 746. The number of grooves 706a-706i can vary.

The zones 787-760 of the heat sources 743 can be arranged in a polygonal shape (as shown in FIG. 7), such as a hexagonal shape (e.g., a close-packed hexagonal shape). The pattern and location of the grooves 706a-706i and the heat sources 743 facilitates good thermal control within the processing chamber 100. The grooves 706a-706i and/or the heat sources 743 may be symmetrically or asymmetrically positioned, and/or can be positioned differently than what is shown in FIG. 7.

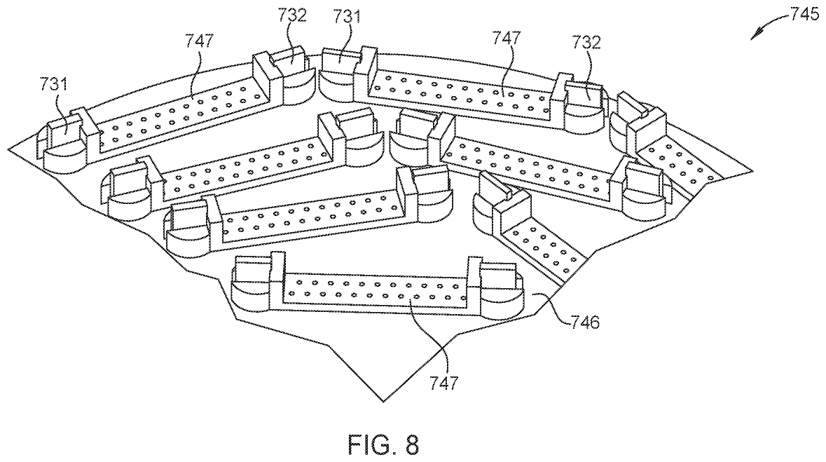

FIG. 8 is a schematic partial bottom perspective view of the heat source module 745 shown in FIG. 7, according to one or more embodiments.

FIG. 8 shows the mount bars 747 coupled to the support plate 746 on the first side of the support plate 746. In one or more embodiments, a pair of socket pins 731, 732 are included such that the respective heat sources 743 can extend through the support plate 746 and the respective mount bars 747 to electrically connect to sockets that include the socket pins 731, 732. The socket pins 731, 732 can electrically connect to one or more electrical power sources.

FIG. 9 is a schematic partial perspective view of one of the heat sources 743 shown in FIG. 7, according to one or more embodiments.

The present disclosure contemplates that the heat source 743 can be used in place of and/or in addition to any of the other heat sources described herein. In one or more embodiments, the heat source 743 is a lamp that is at least partially linear. In one or more embodiments, the heat source 743 is polygonal in shape, such as U-shaped. The heat source 743 includes a bulb 902, one or more arms 904, and one or more electrical connections 906. In one or more embodiments, the heat source 743 is an infrared (IR) halogen lamp. The bulb 902 is a cylindrical bulb with the filament 705 disposed therein. The bulb 902 is configured to emit a radiative energy, such as IR light, towards the substrate 102 when positioned within the processing chamber 100.

The one or more arms 904 extend from the bulb 902. As shown in FIG. 9, there are two arms 904 and one arm extends from the distal ends of the bulb 902. The two arms 904 extend in a direction perpendicular to the direction in which the bulb 902 extends. The two arms 904 extend in the same direction and are configured to pass through the holes 708 of the support plate 746. At the end of each of the arms 904 is an electrical connection 906. The electrical connection 906 is configured to be plugged into or coupled to the sockets or other power source. The electrical connections 906 are electrically coupled to the filament 705 within the bulb 902 and enable the filament 705 to be powered.

FIG. 10 is a schematic partial perspective view of a heat source 1000, according to one or more embodiments.

The present disclosure contemplates that the heat source 1000 can be used in place of and/or in addition to any of the other heat sources described herein. The heat source 1000 includes a curved lamp. In one or more embodiments, the heat source 1000 includes a curved bulb 1008, one or more arms 1010, and one or more electrical connections 1012. The curved bulb 1008 is a tubular bulb that is e.g., arcuate in shape. In one or more embodiments, the curved bulb 1008 is shaped to form at least a portion of a ring. The curved bulb 1008 includes a filament 1005 disposed therein. The curved bulb 1008 is configured to emit a radiative energy towards the substrate 102 when positioned within the processing chamber 100.

The one or more arms 1010 extend from the curved bulb 1008. In one or more embodiments, the heat source 1000 includes two arms 1010, and one arm extends from each distal end of the curved bulb 1008 and orthogonal to a plane of the curved bulb 1008. The two arms 1010 extend in a direction perpendicular to the direction in which the curved bulb 1008 extends arcuately. The two arms 1010 extend in the same direction and are configured to pass through the holes 708. At the respective ends of the arms 1010 is an electrical connection 1012. The electrical connections 1012 are configured to be plugged into or couple to the sockets or other power source. The electrical connections 1012 are electrically coupled to the filament 1005 within the curved bulb 1008 and enable the filament 1005 to be powered.

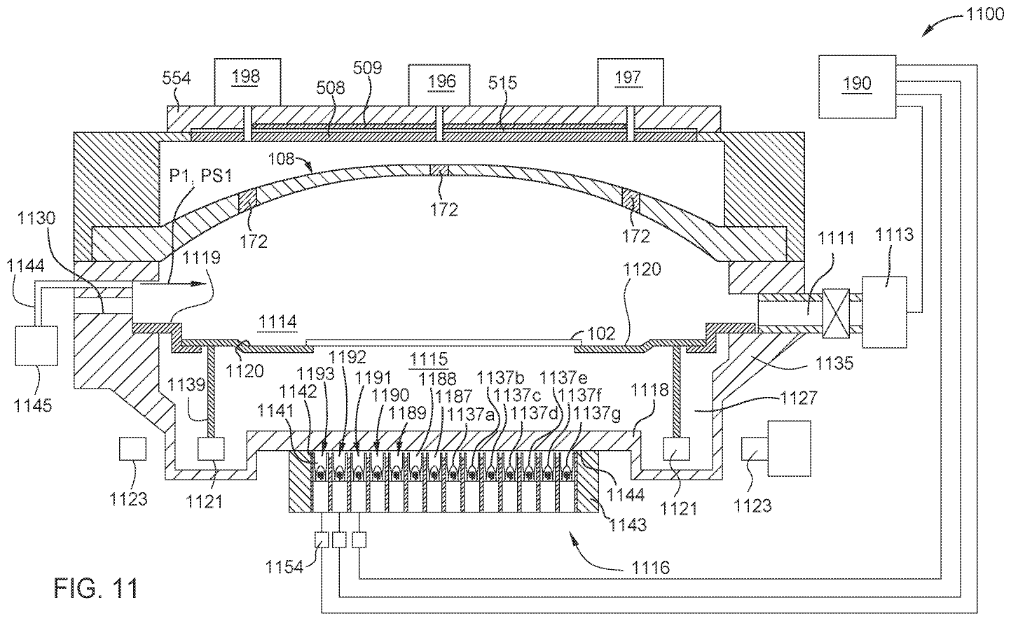

FIG. 11 is a schematic cross-sectional side view of a processing chamber 1100, according to one or more embodiments.

In one or more embodiments, the processing chamber 1100 is deposition chamber, such as an epitaxial deposition chamber. The processing chamber 1100 includes a chamber body 1135 at least partially defining a processing volume 1114 to process the substrate 102. The chamber body 1135 may be made of stainless steel and may be lined with quartz. The processing volume 1114 is configured to be radiantly heated by a heat source module 1116 disposed on a quartz window 1118. In one or more embodiments, the quartz window 1118 is fluid cooled.

The processing chamber 1100 includes the plate 108 shown in FIG. 1 disposed above the substrate support 1120. In FIG. 11, the plate 108 omits the plate opening 174. The processing chamber 1100 includes the cavity 515, the reflector 509, the lid 554, and the sensor devices 196-198 shown in FIG. 5 disposed above the plate 108. The reflector 509 is disposed above the substrate support 1120, and the heat source module 1116 is disposed below the substrate support 1120 to heat the substrate 102 from a backside of the substrate 102, which facilitates temperature uniformity and deposition uniformity.

A slit valve 1130 may be formed on a side of the chamber body 1135 providing a passage for the substrate 102 into and out of the processing volume 1114. A gas inlet 1144 may be connected to flow system 1145 to provide processing gases, purge gases and/or cleaning gases to the processing volume 1114. In one or more embodiments, the flow system 1145 includes an energy source operable to supply the plasma PS1 such that the flow system 1145 can flow both the plasma PS1 and the one or more process gases P1 to the processing volume 1114 through a sidewall of the chamber body 1135 (e.g., through the gas inlet 1144). A vacuum pump 1113 may be fluidly connected to the processing volume 1114 through an outlet 1111 for pumping out the processing volume 1114.

A circular channel 1127 is formed near the bottom of the chamber body 35. A magnetic rotor 1121 is disposed in the circular channel 1127. A tubular riser 1139 rests on or is otherwise coupled to the magnetic rotor 1121. The substrate 102 is supported by a peripheral edge by a substrate support 1120 disposed on the tubular riser 1139. In one or more embodiments, the substrate support 1120 is an edge ring. A magnetic stator 1123 is located externally of the magnetic rotor 1121 and is magnetically coupled through the chamber body 1135 to induce rotation of the magnetic rotor 1121 and hence of the substrate support 1120 and the substrate 102 supported thereon. The magnetic stator 1123 may be also configured to adjust the elevations of the magnetic rotor 1121, thus lifting the substrate 102 being processed.

In one or more embodiments, the reflector 509 is water cooled. In one or more embodiments, the reflector 509 has a diameter larger than the diameter of the substrate 102 being processed. In one or more embodiments, an outer ring 1119 is coupled between the chamber body 1135 and the substrate support 1120 to separate the processing volume 1114 from a purge volume 1115.

The heat source module 1116 includes one or more heat sources 1137. The one or more heat sources 1137 include a plurality of heat sources 1137a-1137g arranged in a plurality of zones 1187-1193 (seven zones are shown in FIG. 11). The heat source module 1116 of the processing chamber 1100 includes a reflector housing 1143, and the heat sources 1137a-1137g are disposed respectively in openings 1141 of the reflector housing 1143. The openings 1141 are oriented parallel (e.g., vertically) to the longitudinal axis L1 of the substrate support 1120. The reflector housing 1143 can be formed of the reflective material and/or can be coated with the reflective material. For example, an upper surface 1144 and/or interior surfaces 1142 adjacent the openings 1141 can be coated with the reflective material. Portions of the reflector housing 1143 are between the openings 1141. One or more cooling channels can be formed in the reflector housing 1143. In one or more embodiments, the plurality of heat sources 1137a-1137g are oriented parallel to the longitudinal axis LA1 of the substrate support 1120. In one or more embodiments

The heat sources 1137 connected to the controller 190 which are capable of adjusting heating effects of the heat sources 1137. In one or more embodiments, the heat sources 1137 are grouped into the zones 1187-1193, and the zones 1187-1193 of the heat sources 1137 can be independently powered using the controller 190. Zones 1187-1193 may be controlled independently to provide a target temperature profile across the substrate 102. The zones 1187-1193 of the heat sources 1137 can be independently pulsed. The zones 1187-1193 can be connected to a respective power source 1054 that can be individually controlled. In one or more embodiments, the amplitude, phase, and/or frequency of power provided to the respective zones 1187-1193 may be independently controlled to adjust radiant energy directed to a corresponding zone of the substrate 102.

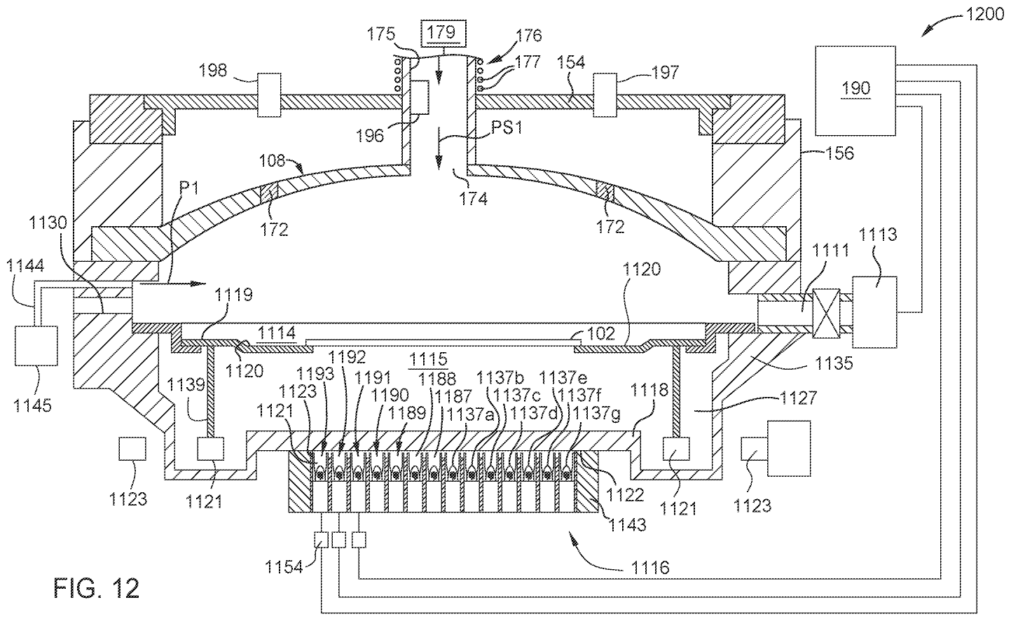

FIG. 12 is a schematic side cross-sectional view of a processing chamber 1200, according to one or more embodiments.

The processing chamber 1200 is similar to the processing chamber 1100 shown in FIG. 11, and includes one or more aspects, features, components, operations, and/or properties thereof.

The processing chamber 1200 includes the plate 108 shown in FIG. 1 disposed above the substrate support 1120. In FIG. 12, the plate 108 includes the plate opening 174. The processing chamber 1200 includes the lid 154, the upper body 156, the conduit 175, the energy source 176 (including the one or more RF coils 177), the plasma gas source 179, and the sensor devices 196-198 shown in FIG. 1 disposed above the plate 108. The processing chamber 1200 includes the plasma gas source 179 shown in FIG. 1. The conductive plate 187 shown in FIG. 1 is not shown in FIG. 12 for visual clarity purposes. The present disclosure contemplates that the conductive plate 187 can be omitted or can be disposed between the plate 108 and the substrate support 1120.

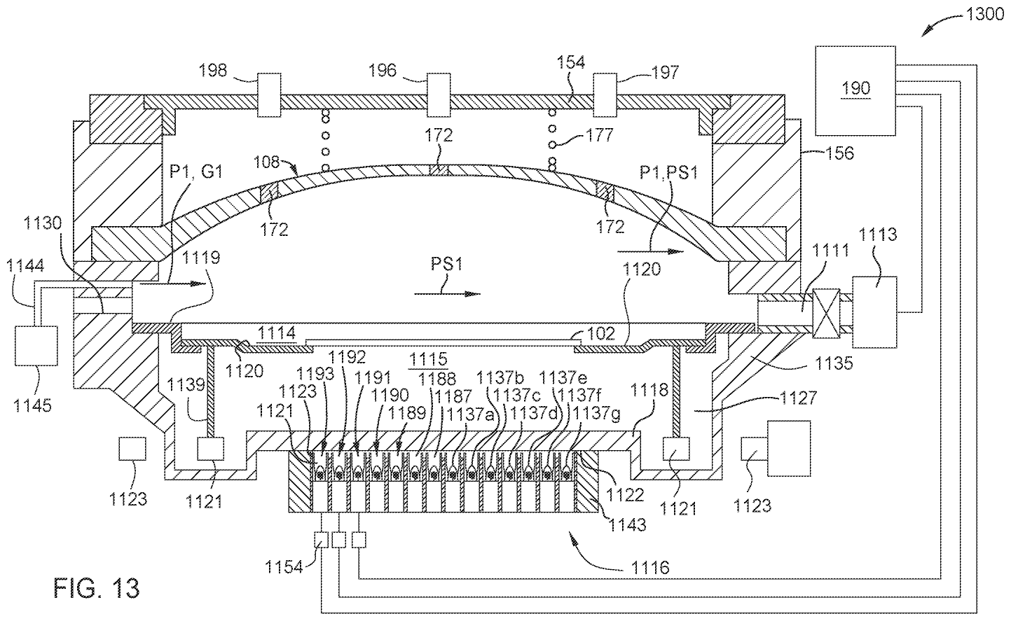

FIG. 13 is a schematic side cross-sectional view of a processing chamber 1300, according to one or more embodiments.

The processing chamber 1300 is similar to the processing chamber 1100 shown in FIG. 11, and includes one or more aspects, features, components, operations, and/or properties thereof.

The processing chamber 1300 includes the plate 108 shown in FIG. 1 disposed above the substrate support 1120. In FIG. 13, the plate 108 omits the plate opening 174. The processing chamber 1300 includes the lid 154, the upper body 156, the energy source 176 (including the one or more RF coils 177), and the sensor devices 196-198 shown in FIG. 1 disposed above the plate 108. The one or more RF coils 177 are disposed between the plate 108 and the lid 154, the gas G1 is supplied from the 1145 while powering the one or more RF coils 177 to generate the plasma PS1 in the processing volume 1114. The conductive plate 187 shown in FIG. 1 is not shown in FIG. 13 for visual clarity purposes. The present disclosure contemplates that the conductive plate 187 can be omitted or can be included.

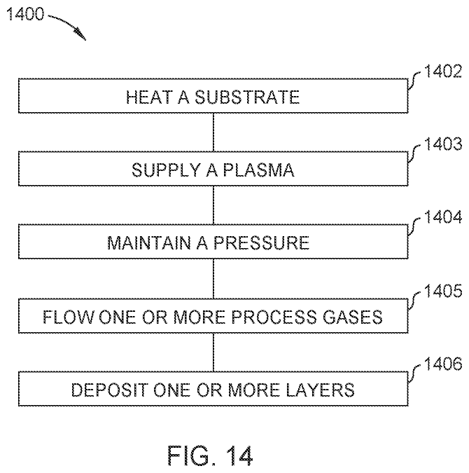

FIG. 14 is a schematic block diagram view of a method 1400 of substrate processing for semiconductor manufacturing, according to one or more embodiments.

Operation 1402 of the method 1400 includes heating a substrate positioned on a substrate support of a processing chamber from one side of the substrate. The heating includes heating the substrate to a target temperature. In one or more embodiments, the target temperature is less than 500 degrees Celsius. In one or more embodiments, the target temperature is 400 degrees Celsius or less.

Operation 1403 includes supplying a plasma in a processing volume of the processing chamber. The plasma can be generated in the processing volume and/or can be generated outside of the processing volume and then flowed into the processing volume.

Operation 1404 includes maintaining the processing volume at a pressure. In one or more embodiments, the pressure is maintained to be less than 60 Torr, such as within a range of 0 Torr to 30 Torr. In one or more embodiments, the pressure is maintained to be less than 1 Torr, such as within a range of 0 Torr to 5 m Torr.

Operation 1405 includes flowing one or more process gases over the substrate. In one or more embodiments, the plasma of operation 1403 is supplied during the flowing of the one or more process gases of operation 1405, and the plasma flows over the substrate. In one or more embodiments, the plasma of operation 1403 is supplied before or after the flowing of the one or more process gases of operation 1405.

Operation 1406 includes depositing one or more layers on the substrate. In one or more embodiments, the plasma of operation 1403 is supplied during the depositing of operation 1406. In one or more embodiments, the plasma of operation 1403 is supplied before or after the depositing of operation 1406.

Benefits of the present disclosure include reliable gas activation (such as at relatively low processing temperatures); adjustability of gas activation; modularity of using plasma operations and epitaxial deposition operations in a single chamber; modularity in chamber application; more uniform gas activation; temperature uniformity (e.g., temperature uniformity in an outer region of the substrate); reduced gas consumption and gas waste; increased growth rates; and more uniform film growth and/or dopant concentration. As an example, ions and/or radicals can be used to activate gases for processing in addition to or in place of electromagnetic radiation (such as infrared radiation and/or ultraviolet radiation).

Benefits also include enhanced device performance; reduced or eliminated occurrences of unintended dopant diffusions; efficient processing; and increased throughput. As an example, the gas activation is facilitated for substrate target temperatures less than 500 degrees Celsius, such as target temperatures within a range of 380 degrees to 500 degrees Celsius. For example, gas can be activated for processing operations when the substrate is at about 400 degrees Celsius.

It is contemplated that one or more aspects disclosed herein may be combined. As an example, one or more aspects, features, components, operations and/or properties of the processing chamber 100; the conductive plate 187; the controller 190; the one or more sensor devices 195, 196, 197, 198; the heat source module 145, the conduit 175, the energy source 176, the processing chamber 300, the heat source module 345, the processing chamber 400, the heat source module 445, the processing chamber 500, the heat source module 545, the energy source 520, the zonal arrangement 600, the heat source module 745, the heat source 743, the heat source 1000, the processing chamber 1100, the heat source module 1116, the processing chamber 1200, the processing chamber 1300, and/or the method 1600 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for use in semiconductor manufacturing, comprising:
a chamber body comprising an inject section and an exhaust section;
a plate, the chamber body and the plate at least partially defining a processing volume, and the plate comprising at least one opaque surface;
one or more heat sources configured to heat the processing volume; and
a substrate support disposed in the processing volume and above the one or more heat sources, the plate disposed between the substrate support and a lid of the processing chamber.

2. The processing chamber of claim 1, wherein the one or more heat sources comprise a plurality of heat sources arranged in a plurality of levels.

3. The processing chamber of claim 2, wherein the plurality of levels comprise:
a first level of one or more first heat sources; and
a second level of one or more second heat sources oriented at an angle relative to the first level.

4. The processing chamber of claim 3, wherein the plurality of levels further comprise:
a third level of one or more third heat sources.

5. The processing chamber of claim 4, further comprising:
a first reflector disposed inwardly of the first level of one or more first heat sources;
a second reflector disposed inwardly of the second level of one or more second heat sources; and
a third reflector disposed inwardly of the third level of one or more third heat sources.

6. The processing chamber of claim 1, wherein the plate comprises a transparent section and an opaque section.

7. The processing chamber of claim 1, further comprising a conductive plate disposed between the substrate support and the plate, wherein the conductive plate comprises a plurality of flow openings.

8. The processing chamber of claim 7, further comprising a ground electrode extending into the conductive plate on a side aligned with the exhaust section of the processing chamber.

9. The processing chamber of claim 7, wherein the plate comprises a plate opening and the processing chamber further comprises:
a conduit in fluid communication with the plate opening; and
one or more radio frequency (RF) coils disposed at least partially about the conduit.

10. The processing chamber of claim 1, wherein the one or more heat sources comprise a plurality of heat sources arranged in a plurality of zones.

11. The processing chamber of claim 10, wherein the plurality of heat sources are oriented parallel to a longitudinal axis of the substrate support.

12. The processing chamber of claim 10, wherein the plurality of heat sources are oriented at an oblique angle relative to a longitudinal axis of the substrate support.

13. A processing chamber applicable for use in semiconductor manufacturing, comprising:
a chamber body comprising an inject section and an exhaust section;
a window, the chamber body and the window at least partially defining a processing volume;
one or more heat sources configured to heat the processing volume;
a substrate support disposed in the processing volume and above the one or more heat sources;
a reflector disposed outwardly of the window relative to the substrate support; and
an energy source operable to supply a plasma in the processing volume.

14. The processing chamber of claim 11, wherein the one or more heat sources comprise a plurality of heat sources arranged in a plurality of levels.

15. The processing chamber of claim 11, wherein the one or more heat sources comprise a plurality of heat sources arranged in a plurality of zones.

16. The processing chamber of claim 15, wherein the plurality of heat sources are oriented parallel to a longitudinal axis of the substrate support.

17. The processing chamber of claim 15, wherein the plurality of heat sources are oriented at an oblique angle relative to a longitudinal axis of to the substrate support.

18. A method of substrate processing, comprising:
heating a substrate positioned on a substrate support of a processing chamber from one side of the substrate;
supplying a plasma in a processing volume of a processing chamber;
flowing one or more process gases over the substrate; and
depositing one or more layers on the substrate.

19. The method of claim 18, wherein the plasma is supplied during the flowing of the one or more process gases, and the plasma flows over the substrate.

20. The method of claim 18, wherein the plasma is supplied before or after the flowing of the one or more process gases.
